(19) United States
(12) Patent Application Publication
(10) Pub. No.: US 2024/0084138 A1
(43) Pub. Date: Mar. 14, 2024

(54) ADDITION CURABLE SILICONE RESIN COMPOSITION AND DIE ATTACHMENT MATERIAL FOR SEMICONDUCTOR DEVICE

(71) Applicant: SHIN-ETSU CHEMICAL CO., LTD., Tokyo (JP)

(72) Inventor: Tatsuya YAMAZAKI, Tomioka-shi (JP)

(73) Assignee: SHIN-ETSU CHEMICAL CO., LTD., Tokyo (JP)

(21) Appl. No.: 18/237,448

(22) Filed: Aug. 24, 2023

(30) Foreign Application Priority Data
Aug. 29, 2022 (JP) 2022-135731

(51) Int. Cl. C08L 83/04

(52) U.S. Cl. CPC C08L 83/04

(57) ABSTRACT

A silicone composition including: (A-1) a branched polysiloxane represented by the formula

(R¹₁R²₂SiO_{1/2})ₐ(R²₃SiO_{1/2})_{b}(R²₂SiO_{2/2})_{c}(R²SiO_{3/2})_{d}(SiO_{4/2})ₑ,

where R¹ represents an alkenyl group, R² represents an alkyl group, and 0.01<a<0.15, 0.3<b<0.6, and 0.25<e<0.67 are satisfied; (A-2) a linear polysiloxane represented by the formula (R¹R²₂SiO_{1/2})₂(R²₂SiO_{2/2})ₓ (R³₂SiO_{2/2}) y, where R³ represents an aryl group, and x>0, y≥0, and 0.85≤(x/(x+y)) are satisfied; (B) a linear polysiloxane represented by the formula

(R²₃SiO_{1/2})₂(HR²SiO_{2/2})ⱼ(R²₂SiO_{2/2})ₖ, where

0.60≤(j/(j+k))≤0.95 is satisfied; (C) a catalyst; and (D) a thermally conductive filler in a flake shape having an average particle size of 3 μm or more, a cured product of the composition having a thermal conductivity of 1.0 W/m·K or more and a storage elastic modulus at −40° C. of 150 MPa or less. This provides a silicone composition having both thermal conductivity and reduced elasticity.

### TECHNICAL FIELD

The present invention relates to an addition curable silicone resin composition and a die attachment material for a semiconductor device.

### BACKGROUND ART

An addition curable silicone resin as a die attach agent in the electronic material field has attracted attention in recent years due to advantages such as higher reliability including humidity resistance and heat resistance, higher stress relaxation ability because of capability of lowering elasticity, and improved handleability as compared with conventional organic polymer resins typified by an epoxy resin and acrylic resin.

In semiconductor applications, as a die attach agent for sensors for mounting a MEMS sensor or CMOS image sensor on a substrate, properties such as suppressing transmission of impact from the substrate side to a chip and relaxing stress in a wide range of operating temperature are required. Compositions whose cured products are gel- or rubber-like methylphenyl silicone resins having few phenyl groups as substituents have a glass transition temperature of −50° C. or less, and are known to have very little change of the storage elastic modulus in a wide temperature range. Therefore, such compositions are preferable for use as a die attach agent for sensors in terms of properties.

In recent years, thermal conductivity is also required in a die attach agent due to increase of heat generation amount along with increasing size of chips, particularly in CMOS image sensors. When the thermal conductivity is imparted to a die attach agent, generally, a silicone resin is highly filled with a thermally conductive filler. However, there is concern that the storage elastic modulus of a cured product becomes high, and warpage of a sensor chip becomes large (Patent Document 1). Meanwhile, in compositions in which a silicone resin itself has low elastic modulus for producing a cured product in a gel form, the elastic modulus can be reduced even when the silicone resin is highly filled with a thermally conductive filler. However, there is concern that the strength for holding sensor chips is decreased (Patent Document 2).

Moreover, silicone resins containing a large amount of low molecular siloxane compounds having a polymerization degree of 10 or less and having high volatility are known to cause various failures when used as a die attach agent for sensors. Particularly in CMOS image sensors, if a low molecular siloxane compound volatized in a process in which thermal history is generated such as a curing process of a die attach agent or reflowing is attached to an on-chip lens formed on an outermost surface of the chip, the attached compound hinders incident light arriving at a color filter, and there is high possibility that operation failure is caused in the operation of a completed package.

Therefore, it is required that a contained amount of low molecular siloxane having a polymerization degree of 10 or less in the entire resin is small.

As described above, in conventional addition curable silicone resin compositions having thermal conductivity, there has been a problem that it is difficult to achieve both thermal conductivity and reduced elasticity in cured products with high resin strength when used as a die attach agent for semiconductor.

### CITATION LIST

### Patent Literature

Patent Document 1: JP 2015-093970 A
Patent Document 2: JP 2013-124257 A

### SUMMARY OF INVENTION

### Technical Problem

The present invention has been made for solving the above problem, and an object thereof is to obtain an addition curable silicone resin composition, a cured product thereof having excellent resin strength, both thermal conductivity and reduced elasticity, and also excellent adhesive strength to a substrate.

### Solution to Problem

For solving the above problems, the present invention provides an addition curable silicone resin composition comprising:
(A-1) a branched organopolysiloxane represented by the following formula (1) containing two or more alkenyl groups having 2 to 8 carbon atoms within one molecule,

(R¹₁R²₂SiO/_{1/2})ₐ(R²₃SiO_{1/2})_{b}(R²₂SiO_{2/2})_{c}(R²SiO_{3/2})_{d}(SiO_{4/2})ₑ (1)

wherein R1 represents an alkenyl group having 2 to 8 carbon atoms, R² independently represents an alkyl group having 1 to 12 carbon atoms, and “a”, “b”, “c”, “d”, and “e” are numbers of 0.01<a<0.15, 0.3<b<0.6, 0<c, 0<d, and 0.25<e<0.67, provided that a+b+c+d+e=1 is satisfied,
(A-2) a linear organopolysiloxane represented by the following formula (2),

(R¹R²₂SiO_{1/2})₂(R²₂SiO_{2/2})ₓ(R³₂SiO_{2/2})_{y} (2)

wherein R¹ and R² are as defined above, R³ independently represents an aryl group having 6 to 12 carbon atoms, and “x” and “y” are numbers of x>0, y≥0, 0.85<(x/(x+y)), and 50≤x+y≤55000,
(B) a linear organohydrogen polysiloxane which is represented by the following formula (3) and contains an organosilicon compound containing a hydrosilyl group and having 1 to 10 silicon atoms in an amount of 5% by mass or less,

(R²₃SiO_{1/2})₂(HR²SiO_{2/2})ⱼ(R²₂SiO_{2/2})ₖ (3)

wherein each R² is as defined above, “j” and “k” are positive numbers of 0.60≤(j/(j+k))≤0.95, and 30≤j+k≤120,
(C) an addition curing catalyst, and
(D) a thermally conductive filler in a flake shape having an average particle size (D50) of 3 μm or more,

wherein

a cured product of the addition curable silicone resin composition has a thermal conductivity of 1.0 W/m·K or more, and further a storage elastic modulus at −40° C. of 150 MPa or less.

Such an addition curable silicone resin composition can provide an addition curable silicone resin composition, a cured product of which has excellent resin strength, and has both thermal conductivity and reduced elasticity.

Moreover, the component (D) is preferably a silver particle.

Such an addition curable silicone resin composition can provide the addition curable silicone resin composition having both thermal conductivity and reduced elasticity in a more improved manner.

Furthermore, the addition curable silicone resin composition preferably comprises, as an adhesion aid (E), a branched organopolysiloxane represented by the following formula (4) having a weight average molecular weight of 1,500 to 8,000 and an epoxy equivalent of 250 to 500 g/eq,

(MeSiO_{3/2})ₚ₁(EpSiO_{3/2})ₚ₂(EpMeSiO_{2/2})_{q1}(Me₂SiO_{2/2})_{q2}(ViMeSiO_{2/2})_{q3}(OR⁵)ᵣ (4)

wherein Me represents a methyl group, Ep represents a monovalent organic group having an epoxy group, Vi represents a vinyl group, R⁵ represents an alkyl group having 1 to 12 carbon atoms, p1, p2, q1, q2, q3, and “r” are numbers of 0≤p1≤0.35, 0≤p2≤0.35, 0≤q1<0.35, 0.4≤q2≤0.7, 0≤q3≤0.1, 0≤r<0.05, and 0.15≤(p2+q1)/(p1+p2+q1+q2+q3+r)≤0.35, provided that p1+p2+q1+q2+q3+r=1.

Such an addition curable silicone resin composition can provide an addition curabie silicone resin cured product having excellent adhesiveness to various substrates typified by an organic substrate.

Additionally, the addition curable silicone resin composition of the present invention preferably further contains an inorganic filler as a component (F).

In the inventive addition curable silicone resin composition, an inorganic filler may be appropriately blended for the purposes of improving the strength of a cured product to be obtained, imparting thixotropy to improve coating workability of a die attachment material, and also suppressing precipitation of a thermally conductive filler during storage.

Further, a low molecular siloxane compound having a polymerization degree of 10 or less is preferably contained in an amount of 1% by mass or less in the entire addition curable silicone resin composition.

With such an addition curable silicone resin composition, it is possible to reduce adhesion of a contaminant to a surrounding member during curing, and suppress failure in a process performed by a customer.

Further, the present invention provides a die attachment material for a semiconductor device composed of the above addition curable silicone resin composition.

Such a die attachment material for a semiconductor device can provide a semiconductor device with high reliability since the thermal conductivity and reduced elasticity can be both achieved, with a cured product having high resin strength.

### Advantageous Effects of Invention

According to the inventive addition curable silicone resin composition, it is possible to provide an addition curable silicone resin composition, a cured product thereof having excellent resin strength, having both thermal conductivity and reduced elasticity, and also having excellent adhesiveness, when used as a die attachment material for a semiconductor device.

Therefore, the inventive addition curable silicone resin composition is quite useful as a die attachment material for a semiconductor device.

Note that the reason why such effects are exerted is conceivably because use of the specific organopolysiloxane in a specific combination can achieve both thermal conductivity and reduced elasticity in a cured product with excellent resin strength, as compared with a normal addition curable silicone resin composition containing a thermally conductive filler.

### DESCRIPTION OF EMBODIMENTS

As described above, it has been demanded to develop an addition curable silicone resin composition, a cured product thereof having excellent resin strength, having both thermal conductivity and reduced elasticity, and also having excellent adhesive strength to a substrate.

The present inventor has made intensive investigations on the above problem, and found that the use of a specific organopolysiloxane in a specific combination can achieve both thermal conductivity and reduced elasticity in a cured product with excellent resin strength, as compared with a normal addition curable silicone resin composition containing a thermally conductive filler. Thus, the present invention has been completed.

That is, the present invention is an addition curable silicone resin composition comprising:
(A-1) a branched organopolysiloxane represented by the following formula (1) containing two or more alkenyl groups having 2 to 8 carbon atoms within one molecule,

(R¹₁R²₂SiO_{1/2})ₐ(R²₃SiO_{1/2})_{b}(R²₂SiO_{2/2})_{c}(R²SiO_{3/2})_{d}(SiO_{4/2})ₑ (1)

wherein R¹ represents an alkenyl group having 2 to 8 carbon atoms, R² independently represents an alkyl group having 1 to 12 carbon atoms, and “a”, “b”, “c”, “d”, and “e” are numbers of 0.01<a<0.15, 0.3<b<0.6, 0≤c, 0≤d, and 0.25<e<0.67, provided that a+b+c+d+e=1 is satisfied,
(A-2) a linear organopolysiloxane represented by the following formula (2),

(R¹R²₂SiO_{1/2})₂(R²₂SiO_{2/2})ₓ(R³₂SiO_{2/2})_{y} (2)

wherein R¹ and R² are as defined above, R³ independently represents an aryl group having 6 to 12 carbon atoms, and “x” and “y” are numbers of x>0, y≥0, 0.85≤(x/(x+y)), and 50≤x+y≤5000,
(B) a linear organohydrogen polysiloxane which is represented by the following formula (3) and contains an organosilicon compound containing a hydrosilyl group and having 1 to 10 silicon atoms in an amount of 5% by mass or less,

(R²₃SiO_{1/2})₂(HR²SiO_{2/2})ⱼ(R²₂SiO_{2/2})ₖ (3)

wherein each R² is as defined above, “j” and “k” are positive numbers of 0.60≤(j/(j+k))≤0.95, and 30≤j+k≤120,
(C) an addition curing catalyst, and
(D) a thermally conductive filler in a flake shape having an average particle size (D50) of 3 μm or more, wherein

a cured product of the addition curable silicone resin composition has a thermal conductivity of 1.0 W/m·K or more, and further a storage elastic modulus at −40° C. of 150 MPa or less.

Hereinafter, the present invention will be described in detail. However, the present invention is not limited thereto.

The inventive addition curable silicone resin composition contains the above components (A-1) to (D), and various known additives may be further added as necessary. Hereinafter, the respective components will be described.
(A-1) Branched Organopolysiloxane

The component (A-1) is a branched organopolysiloxane represented by the following formula (1) containing two or more alkenyl groups having 2 to 8 carbon atoms within one molecule.

(R¹₁R²₂SiO_{1/2})ₐ(R²₃SiO_{1/2})_{b}(R²₂SiO_{2/2})_{c}(R²SiO_{3/2})_{d}(SiO_{4/2})ₑ (1)

In the formula, R¹ represents an alkenyl group having 2 to 8 carbon atoms, R² independently represents an alkyl group having 1 to 12 carbon atoms, and “a”, “b”, “c”, “d”, and “e” are numbers of 0.01<a<0.15, 0.3<b<0.6, 0≤c, 0≤d, and 0.25<e<0.67, provided that a+b+c+d+e=1 is satisfied.

In the above formula (1), specific examples of the alkenyl group having 2 to 8, particularly 2 to 6 carbon atoms of R¹ include a vinyl group, an allyl group, an isopropenyl group, a butenyl group, a pentenyl group, a hexenyl group, and a cyclohexenyl group. Particularly preferred is a vinyl group.

In the above formula (1), specific examples of the alkyl group having 1 to 12, particularly preferably 1 to 10 carbon atoms of R² include alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, and a decyl group. The alkyl group of the R² is preferably an alkyl group such as a methyl group, an ethyl group, a propyl group, and an isopropyl group in view of the heat resistance under high temperature conditions of a silicone cured product produced from the addition curable silicone resin composition to be obtained. Particularly preferred is a methyl group.

Moreover, the content ratio “a” of the R¹₁R²₂SiO_{1/2} unit in the above formula (1) is in the range of 0.01<a<0.15, preferably in the range of 0.03≤a≤0.13 relative to the total of siloxane units a+b+c+d+e=1. Further, the content ratio “b” of the R²₃SiO_{1/2} unit is 0.3<b<0.6, preferably in the range of 0.35≤b≤0.5 relative to the total of siloxane units a+b+c+d+e=1. Further, the content ratio “e” of the SiO_{4/2} unit is 0.25<e<0.67, preferably in the range of 0.3≤e≤0.6 relative to the total of siloxane units a+b+c+d+e=1.

Furthermore, the content ratio “c” of the R²₂SiO_{2/2} unit and the content ratio “d” of the R²SiO_{3/2} unit in the above formula (1) are optional units, and are 0≤c and 0≤d, respectively, relative to the total of siloxane units a+b+c+d+e=1. “c” is preferably 0, and “d” is preferably 0≤d≤30.

The above component (A-1) can be easily synthesized by mixing the compounds serving as unit sources in the above range of the content ratio, and performing cohydrolytic condensation in the presence of an acid, for example.

Herein, examples of the R¹₁R²₂SiO_{1/2} unit source include organosilicon compounds such as triorganochlorosilane, triorganoalkoxysilane, and hexaorganodisiloxane, represented by the following structural formula. However, the R¹₁R²₂SiO_{1/2} unit source that can be used is not limited thereto.

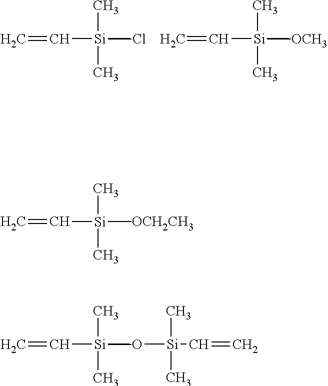

Herein, examples of the R²₃SiO_{1/2} unit source include organosilicon compounds such as triorganochlorosilane, triorganoalkoxysilane, and hexaorganodisiloxane, represented by the following structural formula. However, the R²₃SiO_{1/2} unit source that can be used is not limited thereto.

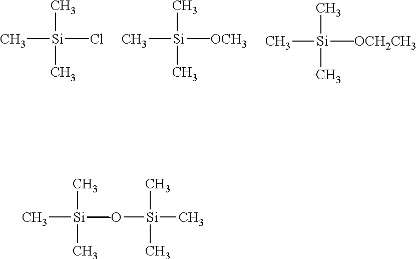

Herein, examples of the SiO_{4/2} unit source include organosilicon compounds such as tetrachlorosilane and tetraalkoxysilane represented by the following structural formula. However, the SiO_{4/2} unit source that can be used is not limited thereto.

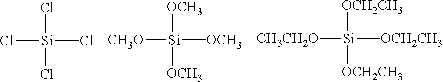

The molecular weight of the component (A-1) is not particularly limited, and may be, for example, 1,000 to 20,000, preferably 2,000 to 10,000, as the weight average molecular weight measured by GPC. The component (A-1) may be a solid or in a liquid state at 25° C.

### (A-2) Linear Organopolysiloxane

The component (A-2) is a linear organopolysiloxane represented by the following formula (2) having two R¹'s (alkenyl groups having 2 to 8 carbon atoms) within one molecule.

(R¹R²₂SiO_{1/2})₂(R²₂SiO_{2/2})ₓ(R³₂SiO_{2/2})_{y} (2)

In the formula, R¹ and R² are the same as above, R³ independently represents an aryl group having 6 to 12 carbon atoms, “x” and “y” are numbers of x>0, y≥0, 0.85≤(x/(x+y)), and 50≤x+y≤5000.

In the above formula (2), specific examples of the alkenyl group having 2 to 8, particularly preferably 2 to 6 carbon atoms of R¹ include a vinyl group, an allyl group, an isopropenyl group, a butenyl group, a pentenyl group, a hexenyl group, and a cyclohexenyl group. Particularly preferred is a vinyl group.

In the above formula (2), specific examples of the alkyl group having 1 to 12, particularly preferably 1 to 10 carbon atoms of R² include alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, and a decyl group. The alkyl group of the R² is preferably an alkyl group such as a methyl group, an ethyl group, a propyl group, and an isopropyl group in view of the heat resistance under high temperature conditions of a silicone cured product produced from the addition curable silicone resin composition to be obtained. Particularly preferred is a methyl group.

In the above formula (2), specific examples of aryl groups having 6 to 12 carbon atoms of R³ include a phenyl group and a naphthyl group. Particularly preferred is a phenyl group. When using such a linear organopolysiloxane to which a predetermined amount of phenyl groups is introduced, the storage elastic modulus, in a low temperature region, of the addition curable silicone resin cured product to be obtained can be suppressed to be low.

In the above formula (2), “x” is a number of x>0, preferably 85 to 3400, and “y” is a number of y≥0, preferably 0 to 600, and more preferably 8 to 600. In addition, “x” and “y” are numbers of 50≤x+y 5000, preferably 100≤x+y≤4000. Furthermore, 0.85≤(x/(x+y)), and preferably 0.90:(x/(x+y)) is satisfied. Within the above range, the compatibility with the component (A-1) and the component (B) described below is preferable, and an addition curable silicone resin cured product having high resin strength is obtained.

The component (A-2) is preferably in a liquid state at 25° C. More preferably, the component (A-2) has a viscosity at 25° C. as measured by a rotary viscometer in the method described in JIS K 7117-1:1999 in the range of 8 to 30,000 mPa·s.

Specific examples of the component (A-2) include the following.

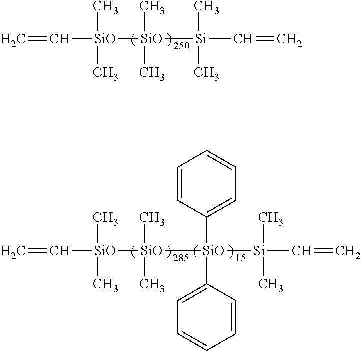

The blending amount of the component (A-2) is, for example, 100 to 3000 parts by mass, preferably 100 to 2000 parts by mass, more preferably 100 to 1000 parts by mas, further more preferably 150 to 950 parts by mass, and extremely preferably 200 to 900 parts by mass, relative to 100 parts by mass of the component (A-1).

### (B) Linear Organohydrogen Polysiloxane

The component (B) is a linear organohydrogen polysiloxane represented by the following formula (3).

(R²₃SiO_{1/2})₂(HR²SiO_{2/2})ⱼ(R²₂SiO_{2/2})ₖ (3)

In the formula, each R² is the same as above, “j” and “k” are positive numbers satisfying 0.60≤(j/(j+k))≤0.95, and 30≤j+k≤120.

Further, the organosilicon compound containing a hydrosilyl group and having 1 to 10 silicon atoms is contained in the component (B) in an amount of 5% by mass or less, and preferably 1% by mass or less.

The component (B) acts as a crosslinking agent. The alkenyl group bonded to a silicon atom (particularly preferably a vinyl group) in the components (A-1) and (A-2) and a hydrogen atom bonded to a silicon atom (hydrosilyl group) in the component (B) undergo an addition reaction, and thereby a silicone cured product is formed from the inventive addition curable silicone resin composition.

A relationship between the contained amount “j” of the HR²SiO_{2/2} unit and the contained amount “k” of the R²₂SiO_{2/2} unit in the above formula (3) satisfies 0.60≤(j/(j+k))≤0.95, and preferably satisfies 0.70≤(j/(j+k))≤0.90. Furthermore, 30≤j+k≤120 is satisfied, and preferably 40≤j+k≤110 is satisfied.

In the above formula (3), each R² is the same as above. The alkyl group of the R² is preferably an alkyl group such as a methyl group, an ethyl group, a propyl group, and an isopropyl group in view of the heat resistance of a silicone cured product produced from the addition curable silicone resin composition to be obtained, when the product is left to stand for a long time under high temperature conditions. Particularly preferred is a methyl group.

Since such a linear organohydrogen polysiloxane richly contains a siloxane unit having a hydrogen atom bonded to a silicon atom on D unit, the curability can be adjusted by steric hindrance during the addition curing reaction. Moreover, such a linear organohydrogen polysiloxane has high wettability with a substrate, and a hydrosilyl group that remains without being incorporated into the addition curing reaction with an alkenyl group due to steric hindrance is converted to a hydroxysilyl group by an addition reaction catalyst, and thereby can contribute to improvement of the adhesiveness to the substrate.

Further, the hydrosilyl group in the linear organohydrogen polysiloxane of the component (B) is preferably contained in an amount of 0.7 to 1.5 mol/100 g, and particularly preferably 1.0 to 1.4 mol/100 g.

Specific examples of the linear organohydrogen polysiloxane of the component (B) include the following.

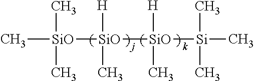

In the formula, “j” and “k” are the same as above.

The blending amount of the component (B) is preferably such that the total hydrogen atoms bonded to silicon atoms in the component (B) is in the range of 1.0 to 2.0 moles, particularly preferably in the range of 1.1 to 1.5 moles relative to 1 mole of the total alkenyl groups bonded to silicon atoms in the entire addition curable silicone resin composition. When the total amount of the hydrogen atoms bonded to silicon atoms in the component (B) is within the above range, the curing reaction proceeds smoothly, and a silicone cured product with high adhesiveness to a substrate can be obtained.

### (C) Addition Curing Catalyst

The addition curing catalyst of the component (C) is blended for promoting the addition curing reaction of the inventive addition curable silicone resin composition. Examples thereof include platinum-based catalysts, palladium-based catalysts, and rhodium-based catalysts. In view of cost or the like, platinum-based catalysts such as platinum and chloroplatinic acid, for example, H₂PtCl₆·mH₂O, K₂PtCl₆, KHPtCl₆·mH₂O, K₂PtCl₄, K₂PtCl₄·mH₂O (“m” represents a positive integer) and the like, or complexes of these materials with hydrocarbon such as olefin, alcohol, or an alkenyl group-containing organopolysiloxane can be exemplified. One of these may be used, or two or more of them may be used in combination. Further, in the platinum-based catalysts, a complex in which a ligand is separated by ultraviolet light to exhibit activity can also be used.

The blending amount of the addition curing catalyst is preferably in the range of 0.1 to 60 ppm, more preferably in the range of 1 to 50 ppm, in the unit of mass of a platinum group metal, relative to 100 parts by mass of the entire addition curable silicone resin composition. When the blending amount of the addition curing catalyst is within the above range, preservability of the addition curable silicone resin composition is preferable, and the addition curing reaction during heating proceeds smoothly.

### (D) Thermally Conductive Filler

The thermally conductive filler in a flake shape having an average particle size (D50) of 3 μm or more of the component (D) is blended for improving the thermal conductivity of the inventive addition curable silicone resin composition. Specifically, the component (D) refers to a filler having the thermal conductivity of 20 W/m·K or more. As a material of the thermally conductive filler, inorganic substances or metals may be selected. Because the storage elastic modulus of a cured product obtained by the addition curable silicone composition can be kept low, and the thermal conductivity is high, flake-shaped silver particles are more preferably used.

The particle size of the thermally conductive filler may be selected according to film thickness during mounting for the intended purpose. When the composition is used as a die attachment material for a semiconductor device, the average particle size of the thermally conductive filler is preferably 3 to 10 μm, and more preferably 4 to 8 μm. Note that the average particle size (D50) as used in the present invention means a median diameter on a volume basis as measured by a laser diffraction method.

The blending amount of the thermally conductive filler is preferably in the range of 65 to 90 parts by mass, more preferably in the range of 70 to 85 parts by mass relative to 100 parts by mass of the entire addition curable silicone resin composition. When the blending amount of the thermally conductive filler is within the above range, a cured product obtained by the addition curable silicone resin composition has suppressed storage elastic modulus, and also shows high strength of the cured product and thermal conductivity.

### (E) Adhesion Aid

Other than the above components (A-1) to (D), an adhesion aid may be added to the inventive addition curable silicone resin composition.

The adhesion aid of the component (E) is blended for allowing a more favorable exhibition of adhesiveness in the cured addition curable silicone resin composition of the present invention to a substrate. The component (E) is a branched organopolysiloxane which is represented by the following formula (4), has a weight average molecular weight of 1,500 to 8,000, and has an epoxy equivalent of 250 to 500 g/eq.

(MeSiO_{3/2})ₚ₁(EpSiO_{3/2})ₚ₂(EpMeSiO_{2/2})_{q1}(Me₂SiO_{2/2})_{q2}(ViMeSiO_{2/2})_{q3}(OR⁵)ᵣ (4)

In the formula, Me represents a methyl group, Ep represents a monovalent organic group having an epoxy group, Vi represents a vinyl group, R⁵ represents an alkyl group having 1 to 12 carbon atoms, and p1 to “r”, which are molar fractions (content ratios) of the repeating units, are numbers of 0≤p1<0.35, 0≤p2≤0.³⁵, 0≤q1≤0.35, 0.4<q2≤0.7, 0≤q3≤0.1, 0≤r<0.05, and 0.15≤(p2+q1)/(p1+p2+q1+q2+q3+r)≤0.35, provided that p1+p2+q1+q2+q3+r=1.

Specific examples of the monovalent organic group having an epoxy group represented by Ep in the above formula (4) include organic groups such as a 3-glycidoxypropyl group, 2-(3,4-epoxycyclohexyl)ethyl group, 5,6-epoxyhexyl group, and 7,8-epoxyoctyl group. Ep is particularly preferably a 3-glycidoxypropyl group in view of preservation stability in a state blended with the addition curable silicone resin composition. Further, the alkyl group having 1 to 12 carbon atoms of R⁵ is particularly preferably a methyl group.

As described above, the branched organopolysiloxane having a large weight average molecular weight and small epoxy equivalent has a large polarity difference between the component (A-1) and the component (A-2), and therefore is easily moved to an interface with the substrate during curing. Thus, favorable adhesiveness can be exhibited. Moreover, owing to having a vinyl group on D unit, the branched organopolysiloxane is incorporated into the addition curable silicone resin composition in the addition curing reaction. Therefore, bleed-out after the curing can be suppressed. Furthermore, since the branched organopolysiloxane is more mildly incorporated into the composition as compared to those having a vinyl group on M unit, it is possible to provide room for the composition to be sufficiently adapted to the substrate.

Further, the content ratio “p1” of the MeSiO_{3/2} unit in the above formula (4) is in the range of 0≤p1<0.35, particularly preferably in the range of 0-p1<0.3 relative to the total of siloxane units
p1+p2+q1+q2+q3+r=1. Further, the content ratio “p2” of the EpSiO_{3/2} unit is in the range of 0≤p2≤0.35, particularly preferably in the range of 0≤p2≤0.3 relative to the total of siloxane units
p1+p2+q1+q2+q3+r=1. Further, the content ratio “q1” of the EpMeSiO_{2/2} unit is in the range of 0-q1≤0.35, particularly preferably in the range of 0≤q1≤0.3 relative to the total of siloxane units
p1+p2+q1+q2+q3+r=1. Furthermore, the content ratio “q2” of the Me₂SiO_{2/2} unit is in the range of 0.4<q2≤0.7, particularly preferably in the range of 0.45≤q2≤0.65 relative to the total of siloxane units
p1+p2+q1+q2+q3+r=1. Furthermore, the content ratio “q3” of the ViMeSiO_{2/2} unit is in the range of 0<q3<0.1, particularly preferably in the range of 0≤q3≤0.08 relative to the total of siloxane units
p1+p2+q1+q2+q3+r=1. Furthermore, the content ratio “r” of the OR⁵ unit is in the range of 0≤r≤0.05, particularly preferably in the range of 0≤r≤0.03 relative to the total of siloxane units p1+p2+q1+q2+q3+r=1.
Furthermore, 0.15≤(p2+q1)/(p1+p2+q1+q2+q3+r)≤0.35 is satisfied.

Additionally, the weight average molecular weight of the branched organopolysiloxane of the above formula (4) is in the range of 1,500 to 8,000, preferably in the range of 2,000 to 7,500. When the weight average molecular weight is 8,000 or less, there is no fear that the silicone resin cured product has a turbid appearance. Meanwhile, when the weight average molecular weight is 1,500 or more, the adhesiveness to the substrate can be sufficiently obtained. Note that the weight average molecular weight Mw referred to in the present invention means a weight average molecular weight measured by gel permeation chromatography (GPC) under the following conditions by using polystyrene as a standard substance.

### Measurement Conditions

Development solvent: tetrahydrofuran (THF)
Flow rate: 0.6 mL/min
Detector: differential refractive index detector (RI)
Column: TSK Guardcolumn SuperH-L
TSKgel SuperH4000 (6.0 mm I.D.×15 cm×1)
TSKgel SuperH3000 (6.0 mm I.D.×15 cm×1)
TSKgel SuperH2000 (6.0 mm I.D.×15 cm×2)
   (All manufactured by Tosoh Corporation)
Column temperature: 40° C.
Sample injection amount: 20 μL (THF solution with concentration of 0.5% by mass)

Further, an epoxy equivalent of the branched organopolysiloxane of the above formula (4) is in the range of 250 to 500 g/eq, preferably in the range of 300 to 450 g/eq. When the epoxy equivalent is 500 g/eq or less, the adhesiveness to the substrate can be sufficiently obtained, and when the epoxy equivalent is 250 g/eq or more, there is no fear that separation from the silicone resin composition occurs.

The above component (E) can be easily synthesized by mixing the compounds serving as unit sources in the above range of content ratio, and performing cohydrolytic condensation in the presence of a base, for example.

Herein, examples of the EpSiO_{3/2} unit source and the EpMeSiO_{2/2} unit source include organosilicon compounds represented by the following structural formula. However, the EpSiO_{3/2} unit source and the EpMeSiO_{2/2} unit source that can be used are not limited thereto.

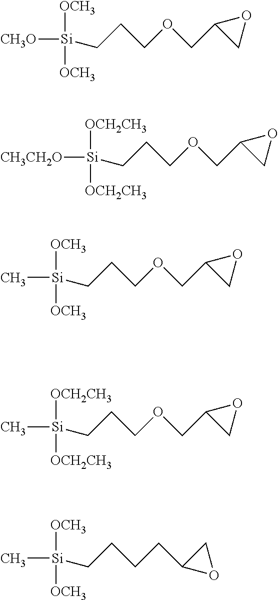

The blending amount of the component (E) is preferably in the range of 0.1 to 10 parts by mass, particularly preferably in the range of 0.2 to 5 parts by mass relative to 100 parts by mass of the entire addition curable silicone resin composition. It is preferable that the blending amount of the component (E) is 0.2 parts by mass or more, since the adhesiveness to the substrate is excellent. Meanwhile, it is preferable that the blending amount is 5 pars by mass or less, since the composition can be used without a problem of coating workability.

### (F) Inorganic Filler

In the inventive addition curable silicone resin composition, an inorganic filler can be appropriately blended for the purpose of improving the strength of a cured product to be obtained, imparting thixotropy to improve the coating workability of a die attachment material, and suppressing precipitation of the thermally conductive filler during storage. Examples of the inorganic filler include fumed silica and quartz powders. Particularly preferably, fumed silica is used.

When the inorganic filler is blended, the blending amount thereof is preferably 10% by mass or less, more preferably may be in the range of 0.1 to 5% by mass relative to 100% by mass of the entire silicone resin composition. In particular, when fumed silica is used as the inorganic filler, the silica surface is preferably treated with a hydrophobic group from the viewpoint of compatibility with the silicone resin. Specific examples of the hydrophobic group include siloxane-based groups such as a trimethylsilyl group and a dimethylsilyl group.

In addition, by the surface treatment, effects such as suppressing interaction between an epoxy group contained in the component (E) and a hydroxysilyl group on the surface of fumed silica, and improving the storage stability can be obtained. Thus, preferably, the surface of fumed silica is sufficiently treated. Specifically, fumed silica having a specific surface area of 150 m²/g or more and 290 m²/g or less, preferably 170 m²/g or more and 230 m²/g or less is preferably used. Examples of fumed silica surface-treated with the above siloxane-based functional group include, as commercially available products, R812 (specific surface area of 230 to 290 m²/g) and RX300 (specific surface area of 180 to 220 m²/g) surface-treated with a trimethylsilyl group, and R976 (specific surface area of 225 to 275 m²/g) and R976S (specific surface area of 215 to 265 m²/g) surface-treated with a dimethylsilyl group, manufactured by NIPPON AEROSIL CO., LTD.

### Curing Inhibitor

A curing inhibitor may be blended to the inventive addition curable silicone resin composition for the purpose of adjusting a curing rate, or the like. Examples of the curing inhibitor include vinyl group-containing organopolysiloxanes, such as tetramethyl tetravinyl cyclotetrasiloxane, hexavinyldisiloxane, and 1,3-divinyl tetramethyldisiloxane, acetylene alcohols, such as ethynyl cyclohexanol and 3·methyl-1-butyne-3-ol, silane-modified products or siloxane-modified products thereof, and compounds selected from the group consisting of hydroperoxide, tetramethyl ethylenediamine, benzotriazole, triallyl isocyanurate, alkyl maleate, and a mixture thereof.

When blending the curing inhibitor, the amount of addition may be preferably 0.001 to 1.0 parts by mass, particularly preferably 0.005 to 0.5 parts by mass relative to 100 parts by mass of the entire silicone resin composition.

### Low Molecular Siloxane Compound

The low molecular siloxane compound having a polymerization degree of 10 or less is preferably contained in the entire addition curable silicone resin composition of the present invention in an amount of preferably 1% by mass or less, more preferably 0.5% by mass or less. When the low molecular siloxane compound having a polymerization degree of 10 or less is contained in the above amount or less, it is possible to obtain a semiconductor package that gives little pollution to a peripheral member and does not damage operation.

Note that the contained amount of the low molecular siloxane compound having a polymerization degree of 10 or less refers to a contained amount of a siloxane compound quantitated by gas chromatography measured under the following conditions in the present invention.

### Measurement Conditions

Apparatus: GC-2014 (manufactured by Shimadzu Corporation)
Column: product name HP-5MS (manufactured by Agilent Technologies, Inc., inner diameter: 0.25 mm, length: 30 m, filler: [(5%-phenyl)-methyl polysiloxane]
Detector: FID detector (detector temperature: 300° C.)
Sample: 1.0 g of sample was dissolved in 10 ml of a standard solution of n-tetradecane/acetone (concentration: 20 μg/mL), and used as a sample.
Injection amount: 1 μL
Oven temperature: 50° C.-280° C./23 minutes—280° C./17 minutes
Carrier gas: type=helium, linear velocity=34.0 cm/s

### Thermal Conductivity

The inventive addition curable silicone resin composition has the thermal conductivity of a resin cured product after curing of 1.0 W/m·K or more, preferably 1.5 W/m·K or more. When the thermal conductivity of a resin cured product after curing is the above value or more, it is possible to suppress power consumption of a semiconductor package or restrain failure by sufficiently dissipating heat generated from a semiconductor chip, when the composition is used as a die attach agent for semiconductor.

Note that, in the present invention, the thermal conductivity of a cured product of the addition curable silicone resin composition may be a value obtained by using a thermal resistance measurement device (manufactured by Hitachi Technologies and Services, Ltd.) for resin material, applying the steady state method as a measurement principle.

### Storage Elastic Modulus at −40° C.

The inventive addition curable silicone resin composition has the storage elastic modulus of a resin cured product after curing at −40° C. of 150 Mpa or less, preferably 100 Mpa or less. When the storage elastic modulus of a resin cured product at −40° C. after curing is the above value or less, warpage of a semiconductor package in an operating temperature range is small, and operation failure can be suppressed.

Note that, in the present invention, the storage elastic modulus of a cured product of the addition curable silicone resin composition at −40° C. may be a value measured using a dynamic viscoelastic measuring device (DMA) “Q800” manufactured by TA Instruments Japan Inc.

The inventive addition curable silicone resin composition can be cured after being applied on a substrate according to the use. The composition can be heated and cured in the temperature range of 70 to 130° C., more preferably 90 to 1200° C. The heating temperature is preferably within the above range since adhesive strength between the substrate and resin cured product is improved, and a semiconductor package with small warpage can be provided. Note that the above heating and curing time may be 0.5 to 2.5 hours, and a stepped curing method may be employed.

The inventive addition curable silicone resin composition can provide an addition curable silicone resin composition having excellent resin strength as compared with an ordinary addition curable silicone resin composition, by using the above specific organopolysiloxane in a specific combination.

Therefore, the composition can be suitably used in electric/electronic component applications. More specifically, the composition can be suitably used as a die attachment material for a semiconductor device.

### EXAMPLE

Hereinafter, the present invention will be specifically described with reference to Examples and Comparative Examples. However, the present invention is not limited thereto.

Note that the part represents “the part by mass”, Me represents a “methyl group”, Vi represents a “vinyl group”, and Ep′ represents a “γ-glycidoxy propyl group”, respectively. Moreover, the weight average molecular weight refers to a weight average molecular weight measured under the aforementioned conditions by GPC measurement. Further, in the following Examples, an amount of SiH groups indicates a number of moles of hydrogen atoms directly bonded to silicon atoms in the molecule, and determined by 1H-NMR measurement using a nuclear magnetic resonance (NMR) apparatus manufactured by Bruker Co., Ltd., and the value is quantitated with dimethyl sulfoxide (DMSO) as an internal standard. An amount of SiVi groups indicates a number of moles of vinyl groups directly bonded to silicon atoms in the molecule, and determined by 1H-NMR measurement using a nuclear magnetic resonance (NMR) apparatus manufactured by Bruker Co., Ltd., and the value is quantitated with DMSO as an internal standard.

### Component (A-1)

(a1-1): A branched organopolysiloxane that is solid at 25° C., has siloxane units of ViMe₂SiO_{1/2} unit (10 mole %), Me₃SiO_{1/2} unit (40 mole %), and SiO_{4/2} unit (50 mole %), contains SiVi groups in an amount of 0.08 mol/100 g, has a weight average molecular weight of 5,600 as measured by GPC, and contains the low molecular siloxane compound having a polymerization degree of 10 or less in an amount of 0.1% by mass.
(a1-2): A branched organopolysiloxane that is liquid at 25° C., has siloxane units of ViMe₂SiO_{1/2} unit (10 mole %), Me₃SiO/_{1/2} unit (35 mole %), MeSiO_{3/2} unit (25 mole %), and SiO_{4/2} unit (30 mole %), contains SiVi groups in an amount of 0.09 mol/100 g, has a weight average molecular weight of 4,900 as measured by GPC, and contains the low molecular siloxane compound having a polymerization degree of 10 or less in an amount of 0.1% by mass.

### Component (A-2)

(a2-1): A linear organopolysiloxane that is represented by the following formula:
(ViMe₂SiO_{1/2})₂(Ph₂SiO_{2/2})₂₀(Me₂SiO_{2/2})₃₅₀, contains SiVi groups in an amount of 0.006 mol/100 g, is liquid at 25° C., contains the low molecular siloxane compound having a polymerization degree of 10 or less in an amount 0.1% by mass, and has a viscosity at 25° C. of 5,100 mPa·s.
(a2-2): A linear organopolysiloxane that is represented by the following formula: (ViMe₂SiO_{1/2})₂(Me₂SiO_{2/2}) 388, contains SiVi groups in an amount of 0.006 mol/100 g, is liquid at 25° C., contains the low molecular siloxane compound having a polymerization degree of 10 or less in an amount of 0.1% by mass, and has a viscosity at 25° C. of 5,000 mPa·s.

### Component (B)

(b-1): An organohydrogen polysiloxane that is represented by the following formula:
(Me₃SiO/_{1/2})₂(HMeSiO_{2/2})₇₂(Me₂SiO_{2/2})₂₄, contains hydrosilyl groups in an amount of 1.14 mol/100 g, is liquid at 25° C., contains the low molecular siloxane compound having a polymerization degree of 10 or less in an amount of 0.1% by mass, and has a viscosity at 25° C. of 163 mPa·s.
(b-2): An organohydrogen polysiloxane that is represented by the following formula:
(Me₃SiO/_{1/2})₂(HMeSiO_{2/2})₈₆(Me₂SiO_{2/2})₁₀, contains hydrosilyl groups in an amount of 1.40 mol/100 g, is liquid at 25° C., contains the low molecular siloxane compound having a polymerization degree of 10 or less in an amount 0.1% by mass, and has a viscosity at 25° C. of 165 mPa·s.

### Component (C)

(c-1): A 1,3-divinyltetramethyldisiloxane solution of a platinum (0)-1,3-divinyltetramethyldisiloxane complex that contains platinum in an amount of 2% by mass, and contains SiVi groups in an amount of 1.05 mol/100 g.

### Component (D)

(d-1): Flake-shaped silver powders “AgC-237” (manufactured by Fukuda Metal Foil & Powder Co., Ltd.) with the average particle size (D50) of 6.5 μm
(d-2): Flake-shaped silver powders “AgC-239” (manufactured by Fukuda Metal Foil & Powder Co., Ltd.) with the average particle size (D50) of 2.4 μm (for comparison)
(d-3): Flake-shaped silver powders “FA-D-1” (manufactured by DOWA Electronics Materials Co., Ltd.) with the average particle size (D50) of 4.2 μm
(d-4): Flake-shaped silver powders “AgC-223” (manufactured by Fukuda Metal Foil & Powder Co., Ltd.) with the average particle size (D50) of 7.6 μm
(d-5): Spherical silver-plated copper core powders “TFM-C05P” with the average particle size (D50) of 6.1 μm (manufactured by TOYO ALUMINIUM K. K.) (for comparison)
(d-6): Spherical aluminum oxide “AC-9204” with the average particle size (D50) of 5.7 μm (manufactured by Admatechs Co., Ltd.) (for comparison)

### Component (E)

(e-1): A branched organopolysiloxane that has siloxane units of Ep′SiO_{3/2} unit (29 mole %), Me₂SiO_{2/2} unit (64 mole %), ViMeSiO_{2/2} unit (6 mole %), and OMe unit (1 mole %), has a weight average molecular weight of 2,400, contains SiVi groups in an amount of 0.05 mol/100 g, has an epoxy equivalent of 330 g/eq, is liquid at 25° C., contains the low molecular siloxane compound having a polymerization degree of 10 or less in an amount of 0.3% by mass, and has a viscosity at 25° C. of 350 mPa·s.
(e-2): A branched organopolysiloxane that has siloxane units of MeSiO_{3/2} unit (25 mole %), Ep′MeSiO_{2/2} unit (22 mole %), Me₂SiO_{2/2} unit (47 mole %), ViMeSiO_{2/2} unit (5 mole %), and OMe unit (1 mole %), has a weight average molecular weight of 4,500, contains SiVi groups in an amount of 0.05 mol/100 g, has an epoxy equivalent of 435 g/eq, is liquid at 25° C., contains the low molecular siloxane compound having a polymerization degree of 10 or less in an amount of 0.1% by mass, and has a viscosity at 25° C. of 355 mPa·s.

### Component (F)

(f-1): Fumed silica “RX300” manufactured by NIPPON AEROSIL CO., LTD.

### Curing Inhibitor

(g-1): Ethynyl cyclohexanol

### Examples 1 to 8, Comparative Examples 1 to 5

Addition curable silicone resin compositions of Examples 1 to 8 and Comparative Examples 1 to 5 were prepared in the blending ratios shown in Tables 1 and 2 (numerical values are parts by mass). Then, for each composition, the hardness, tensile strength, elongation at break, storage elastic modulus of a cured product at −40° C., adhesiveness, thermal conductivity, contained amount of the low molecular siloxane compound having a polymerization degree of 10 or less, and storage stability were evaluated in accordance with the testing methods shown below. The respective measurement results are shown in Tables 1 and 2.

### (a) Hardness

Silicone cured products were produced by heating the addition curable silicone resin compositions at 100° C. for 1 hour using a hot-air circulation drying machine. The hardness of the silicone cured products were measured using a type A durometer in accordance with JIS K 6253-3:2012.

### (b) Tensile Strength and Elongation at Break

Silicone cured products were produced by heating the addition curable silicone resin compositions at 100° C. for 1 hour using a hot-air circulation drying machine. The tensile strength and elongation at break of the silicone cured products were measured in accordance with JIS K 6250.

(c) Storage elastic modulus of cured product at −40° C.

Sheet-shaped silicone cured products with 2 mm thickness were produced by heating the addition curable silicone resin compositions at 100° C. for 1 hour using a hot-air circulation drying machine. The storage elastic modulus of the silicone cured products at −40° C. was measured using a dynamic viscoelastic measuring device (DMA) “Q800” manufactured by TA Instruments Japan Inc.

### (d) Adhesiveness

The addition curable silicone resin compositions were applied on a glass epoxy substrate FR-4 in a predetermined amount, Si chips with a size of 3.0 mm×3.0 mm were die-bonded, and then the compositions were heated and cured at 100° C. for 1 hour using a hot-air circulation drying machine. After the heating, the packages were taken out and cooled to 25° C. Then, the adhesive strength between the chip and substrate of each resin cured product was measured using a bond tester (manufactured by Nordson Advanced Technology K. K.: Dage4000) for 50 times of test to calculate the average adhesive strength.

### (e) Thermal Conductivity

Sheet-shaped silicone cured products with thicknesses of 0.5 mm, 1 mm, and 2 mm were produced by heating the addition curable silicone resin compositions at 100° C. for 1 hour using a hot-air circulation drying machine.

The cured products with the respective thicknesses were cut into 10 mm squares, and thermal resistance values for each thickness were obtained by using a thermal resistance measurement device for resin material applying the steady state method as a measurement principle (manufactured by Hitachi Technologies and Services, Ltd.) (load: 100 kPa). After three measurement results were plotted as points, an approximate curve was drawn by linear approximation, and then the thermal conductivity of the respective resin cured products was calculated from an inclination of the linear approximate curve and size of the cured products.

### (f) Contained Amount of Low Molecular Siloxane Compound Having Polymerization Degree of 10 or Less

The contained amount of the low molecular siloxane compound having a polymerization degree of 10 or less in the addition curable silicone resin compositions was measured using the same method as described above.

(g) Storage Stability

The addition curable silicone resin compositions were stored in a freezer at −20° C. for 1 month, and then thawed under normal temperature. The surface state was then observed. Compositions in which no separation between a resin content and filler was observed were rated as “good”, and compositions in which the separation was observed were rated as “poor”.

TABLE 1

| | | Ex.1 | Ex.2 | Ex.3 | Ex. 4 | Ex.5 | Ex. 6 | Ex.7 | Ex.8 |
|---|---|---|---|---|---|---|---|---|---|
| (A-1) | (a1-1) | 1.70 | 1.70 | 1.70 | 1.70 | | 1.70 | 1.70 | 3.40 |
| | (a1-2) | | | | | 1.70 | | | |
| (A-2) | (a2-1) | 30.05 | 30.05 | 30.05 | 30.05 | 30.05 | | 30.05 | 28.20 |
| | (a2-2) | | | | | | 30.05 | | |
| (B) | (b-1) | 0.60 | 0.60 | 0.60 | 0.60 | 0.60 | 0.60 | | 0.75 |
| | (b-2) | | | | | | | 0.60 | |
| (C) | (c-1) | 0.10 | 0.10 | 0.10 | 0.10 | 0.10 | 0.10 | 0.10 | 0.10 |
| (D) | (d-1) | 166.00 | 166.00 | | | 166.00 | 166.00 | 166.00 | 166.00 |
| | (d-2) | | | | | | | | |
| | (d-3) | | | 166.00 | | | | | |
| | (d-4) | | | | 166.00 | | | | |
| | (d-5) | | | | | | | | |
| | (d-6) | | | | | | | | |
| (E) | (e-1) | 0.50 | | 0.50 | 0.50 | 0.50 | 0.50 | 0.50 | 0.50 |
| | ( e-2) | | 0.50 | | | | | | |
| (F) | (f-1) | 1.00 | 1.00 | 1.00 | 1.00 | 1.00 | 1.00 | 1.00 | 1.00 |
| (G) | (g-1) | 0.05 | 0.05 | 0.05 | 0.05 | 0.05 | 0.05 | 0.05 | 0.05 |

| | | | | | | | | |
|---|---|---|---|---|---|---|---|---|
| SiH/SiVi | 1.3 | 1.3 | 1.3 | 1.3 | 1.3 | 1.3 | 1.6 | 1.3 |
| Hardness | 60 | 58 | 68 | 55 | 56 | 57 | 62 | 72 |
| (Type A) | | | | | | | | |
| Tensile strength | 2.5 | 2.3 | 1.8 | 3.2 | 2.4 | 2.7 | 2.6 | 2.7 |
| ( MPa ) | | | | | | | | |
| Elongation at | 250 | 230 | 180 | 280 | 230 | 275 | 240 | 175 |
| break (%) | | | | | | | | |
| Storage elastic | 75 | 68 | 98 | 53 | 81 | 95 | 81 | 97 |
| modulus at | | | | | | | | |
| −40° C. (MPa) | | | | | | | | |
| Adhesiveness: | 3.4 | 3.6 | 3.1 | 3.7 | 3.3 | 3.5 | 3.6 | 3.8 |
| adhesive | | | | | | | | |
| strength (Kgf) | | | | | | | | |
| Thermal | 2.0 | 1.9 | 1.6 | 2.3 | 2.0 | 2.0 | 2.1 | 1.9 |
| conductivity | | | | | | | | |
| (W/m · K) | | | | | | | | |
| Contained amount | 0.1 | 0.1 | 0.1 | 0.1 | 0.1 | 0.1 | 0.1 | 0.1 |
| of low molecular | | | | | | | | |
| siloxane | | | | | | | | |
| compound having | | | | | | | | |
| polymerization | | | | | | | | |
| degree of | | | | | | | | |
| 10 or less (% by | | | | | | | | |
| weight) | | | | | | | | |
| Storage stability | Good | Good | Good | Good | Good | Good | Good | Good |

TABLE 2

| | | Comp.Ex.1 | Comp.Ex.2 | Comp. Ex.3 | Comp. Ex. 4 | Comp. Ex.5 |
|---|---|---|---|---|---|---|
| (A-1) | (a1-1) | 3.40 | 10.00 | | 1.70 | 1.70 |
| | (a1-2) | | | | | |
| (A-2) | (a2-1) | 28.20 | 86.75 | 31.93 | 30.05 | 30.05 |
| | (a2-2) | | | | | |
| (B) | (b-1) | 0.75 | 1.60 | 0.42 | 0.60 | 0.60 |
| | (b-2) | | | | | |
| (C) | (c-1) | 0.10 | 0.10 | 0.10 | 0.10 | 0.10 |
| (D) | (d-1) | | | 166.00 | | |
| | (d-2) | 166.00 | | | | |
| | (d-3) | | | | | |
| | (d-4) | | | | | |
| | (d-5) | | | | 166.00 | |
| | (d-6) | | | | | 166.00 |
| (E) | (e-1) | 0.50 | 0.50 | 0.50 | 0.50 | 0.50 |
| | (e-2) | | | | | |
| (F) | (f-1) | 1.00 | 1.00 | 1.00 | 1.00 | 1.00 |
| (G) | (g-1) | 0.05 | 0.05 | 0.05 | 0.05 | 0.05 |

| | | | | | |
|---|---|---|---|---|---|
| SiH/SIVi | 1.3 | 1.2 | 1.2 | 1.3 | 1.3 |
| Hardness (Type A) | 92 | 34 | 40 | 48 | 88 |
| Tensile strength | 1.4 | 2.9 | 0.5 | 2.1 | 3.2 |
| (MPa) | | | | | |
| Elongation at break | 65 | 220 | 240 | 280 | 170 |
| (%) | | | | | |
| Storage elastic | 175 | 1.5 | 6 | 48 | 183 |
| modulus | | | | | |
| at −40° C. (MPa) | | | | | |
| Adhesiveness: | 1.5 | 6.8 | 0.3 | 3.2 | 3.7 |
| adhesive strength (Kgf) | | | | | |
| Thermal conductivity | 0.9 | 0.2 | 1.8 | 1.5 | 1.3 |
| (W/m · K) | | | | | |
| Contained amount of | 0.1 | 0.1 | 0.1 | 0.1 | 0.1 |
| low molecular | | | | | |
| siloxane compound | | | | | |
| having | | | | | |
| polymerization | | | | | |
| degree of 10 or less | | | | | |
| (% by weight) | | | | | |
| Storage stability | Good | Good | Good | Poor | Good |

As a result of the above evaluation tests, it was found that the addition curable silicone resin compositions of the present invention (Examples 1 to 8) had excellent resin strength, and also achieved both thermal conductivity and reduced elasticity. On the other hand, in Comparative Example 1, since the average particle size (D50) of the component (D) was less than 3 μm, the storage elastic modulus at −40° C. was high, and the thermal conductivity was low. In Comparative Example 2, a thermally conductive filler was not contained, and thus the thermal conductivity was low. In Comparative Example 3, the component (A-1) was not blended, and the strength and adhesiveness of the resin cured product were extremely low. Furthermore, in Comparative Example 4, since the component (D) did not have a flake shape, component separation was observed during storage. Also in Comparative Example 5, since the component (D) did not have a flake shape, the storage elastic modulus of the cured product at −40° C. was excessively high. Accordingly, it was confirmed that the inventive addition curable silicone resin composition has excellent resin strength, and can achieve both thermal conductivity and reduced elasticity, and therefore is very useful as a die attachment material for a semiconductor device.

The present description includes the following embodiments.
[1]: An addition curable silicone resin composition comprising:
(A-1) a branched organopolysiloxane represented by the following formula (1) containing two or more alkenyl groups having 2 to 8 carbon atoms within one molecule,

(R¹1R²₂SiO_{1/2})ₐ(R²₃SiO_{1/2})_{b}(R²₂SiO_{2/2})_{c}(R²SiO_{3/2})_{d}(SiO_{4/2})ₑ (1)

wherein R¹ represents an alkenyl group having 2 to 8 carbon atoms, R² independently represents an alkyl group having 1 to 12 carbon atoms, and “a”, “b”, “c”, “d”, and “e” are numbers of 0.01≤a≤0.15, 0.3≤b≤0.6, 0≤c, 0≤d, and 0.25≤e≤0.67, provided that a+b+c+d+e=1 is satisfied,
(A-2) a linear organopolysiloxane represented by the following formula (2),

(R¹R²₂SiO_{1/2})₂(R²₂SiO_{2/2})(R³₂SiO_{2/2})_{y} (2)

wherein R¹ and R² are as defined above, R³ independently represents an aryl group having 6 to 12 carbon atoms, and “x” and “y” are numbers of x>0, y≥0, 0.85≤(x/(x+y)), and 50≤x+y≤5000,
(B) a linear organohydrogen polysiloxane which is represented by the following formula (3) and contains an organosilicon compound containing a hydrosilyl group and having 1 to 10 silicon atoms in an amount of 5% by mass or less,

(R²₃SiO_{1/2})₂(HR²SiO_{2/2})ⱼ(R²₂SiO_{2/2})ₖ (3)

wherein each R² is as defined above, “j” and “k” are positive numbers of 0.60≤(j/(j+k))≤0.95, and 30≤j+k≤120,
(C) an addition curing catalyst, and
(D) a thermally conductive filler in a flake shape having an average particle size (D50) of 3 μm or more, wherein

a cured product of the addition curable silicone resin composition has a thermal conductivity of 1.0 W/m·K or more, and further a storage elastic modulus at −40° C. of 150 MPa or less.
[2]: The addition curable silicone resin composition of the above [1], wherein the component (D) is a silver particle.
[3]: The addition curable silicone resin composition of the above [1] or [2], further comprising, as an adhesion aid (E), a branched organopolysiloxane represented by the following formula (4) having a weight average molecular weight of 1,500 to 8,000 and an epoxy equivalent of 250 to 500 g/eq,

(MeSiO_{3/2})ₚ₁(EpSiO_{3/2})ₚ₂(EpMeSiO_{2/2})_{q1}(Me₂SiO_{2/2})_{q2}(ViMeSiO_{2/2})_{q3}(OR⁵)ᵣ (4)

wherein Me represents a methyl group, Ep represents a monovalent organic group having an epoxy group, Vi represents a vinyl group, R⁵ represents an alkyl group having 1 to 12 carbon atoms, p1, p2, q1, q2, q3, and “r” are numbers of 0≤p1<0.35, 0≤p2≤0.35, 0<q1≤0.35, 0.4<q2≤0.7, 0≤q3≤0.1, 0≤r≤0.05, and 0.15≤(p2+q1)/(p1+p2+q1+q2+q3+r)≤0.35, provided that p1+p2+q1+q2+q3+r=1.
[4]: The addition curable silicone resin composition of any one of the above [1] to [3], further comprising an inorganic filler as a component (F).
[5]: The addition curable silicone resin composition of any one of the above [1] to [4], wherein a low molecular siloxane compound having a polymerization degree of 10 or less is contained in an amount of 1% by mass or less in the entire addition curable silicone resin composition.
[6]: A die attachment material for a semiconductor device composed of the addition curable silicone resin composition of any one of the above [1] to [5].

It should be noted that the present invention is not limited to the above-described embodiments. The embodiments are just examples, and any examples that substantially have the same configuration and demonstrate the same functions and effects as those in the technical concept disclosed in claims of the present invention are included in the technical scope of the present invention.

1. An addition curable silicone resin composition comprising:
(A-1) a branched organopolysiloxane represented by the following formula (1) containing two or more alkenyl groups having 2 to 8 carbon atoms within one molecule,
(R¹₁R²₂SiO/_{1/2})ₐ(R²₃SiO/_{1/2})_{b}(R²₂SiO_{2/2})_{c}(R²SiO_{3/2})ₐ(SiO_{4/2})ₑ (1)
wherein R¹ represents an alkenyl group having 2 to 8 carbon atoms, R² independently represents an alkyl group having 1 to 12 carbon atoms, and “a”, “b”, “c”, “d”, and “e” are numbers of 0.01≤a≤0.15, 0.3≤ab≤0.6, 0≤c, 0≤d, and 0.25≤e≤0.67, provided that a+b+c+d+e=1 is satisfied,
(A-2) a linear organopolysiloxane represented by the following formula (2),
(R¹R²₂SiO_{1/2})₂(R²₂SiO_{2/2})ₓ(R³₂SiO_{2/2})_{y} (2)
wherein R¹ and R² are as defined above, R³ independently represents an aryl group having 6 to 12 carbon atoms, and “x” and “y” are numbers of x>0, y≥0, 0.85≤(x/(x+y)), and 50≤x+y≤5000,
(B) a linear organohydrogen polysiloxane which is represented by the following formula (3) and contains an organosilicon compound containing a hydrosilyl group and having 1 to 10 silicon atoms in an amount of 5% by mass or less,
(R²₃SiO_{1/2})₂(HR²SiO_{2/2})ⱼ(R²₂SiO_{2/2})ₖ (3)
wherein each R² is as defined above, “j” and “k” are positive numbers of 0.60 (j/(j+k))≤0.95, and 30 j+k≤120,
(C) an addition curing catalyst, and
(D) a thermally conductive filler in a flake shape having an average particle size (D50)—of 3 μm or more, wherein
a cured product of the addition curable silicone resin composition has a thermal conductivity of 1.0 W/m·K or more, and further a storage elastic modulus at −40° C. of 150 MPa or less.

2. The addition curable silicone resin composition according to claim 1, wherein the component (D) is a silver particle.

3. The addition curable silicone resin composition according to claim 1, further comprising, as an adhesion aid (E), a branched organopolysiloxane represented by the following formula (4) having a weight average molecular weight of 1,500 to 8,000 and an epoxy equivalent of 250 to 500 g/eq,
(MeSiO_{3/2})ₚ₁(EpSiO_{3/2})ₚ₂(EpMeSiO_{2/2})_{q1}(Me₂SiO_{2/2})_{q2}(ViMeSiO_{2/2})_{q3}(OR⁵)ᵣ (4)
wherein Me represents a methyl group, Ep represents a monovalent organic group having an epoxy group, Vi represents a vinyl group, R⁵ represents an alkyl group having 1 to 12 carbon atoms, p1, p2, q1, q2, q3, and “r” are numbers of 0≤p1<0.35, 0≤p2≤0.35, 0≤q1≤0.35, 0.4≤q2≤0.7, 0≤q3≤0.1, 0≤r≤0.05, and 0.15≤(p2+q1)/(p1+p2+q1+q2+q3+r)≤0.35, provided that p1+p2+q1+q2+q3+r=1.

4. The addition curable silicone resin composition according to claim 1, further comprising an inorganic filler as a component (F).

5. The addition curable silicone resin composition according to claim 1,
wherein a low molecular siloxane compound having a polymerization degree of 10 or less is contained in an amount of 1% by mass or less in the entire addition curable silicone resin composition.

6. A die attachment material for a semiconductor device composed of the addition curable silicone resin composition according to claim 1.

7. A die attachment material for a semiconductor device composed of the addition curable silicone resin composition according to claim 2.

8. A die attachment material for a semiconductor device composed of the addition curable silicone resin composition according to claim 3.

9. A die attachment material for a semiconductor device composed of the addition curable silicone resin composition according to claim 4.

10. A die attachment material for a semiconductor device composed of the addition curable silicone resin composition according to claim 5.
